(19) United States
(12) Patent Application Publication
(10) Pub. No.: US 2026/0291528 A1
(43) Pub. Date: Sep. 24, 2026

(54) MATCHING CIRCUIT FOR ANTENNAS

(71) Applicant: Kinneret Smart Waves Ltd. / KSW Antennas, Tiberias (IL)

(72) Inventors: Matti Martiskainen, Aniam (IL); Sharon Harel, Tiberias (IL); Victor Hoepfner, Tiberias (IL); Yaniv Ziv, Tiberias (IL)

(73) Assignee: Kinneret Smart Waves Ltd. / KSW Antennas, Tiberias (IL)

(21) Appl. No.: 19/476,682

(22) PCT Filed: Apr. 18, 2024
(86) PCT No.: PCT/IB2024/053773

§ 371 Date: Oct. 17, 2025

Related U.S. Application Data
(60) Provisional application No. 63/496,949, filed on Apr. 18, 2023.

(51) Int. Cl. H04B 1/04; H03H 7/01; H03H 7/38; H03H 7/46

(52) U.S. Cl. CPC H04B 1/0458; H03H 7/0115; H03H 7/461; H03H 2007/386

(57) ABSTRACT

A matching circuit for matching an impedance of an antenna to an output impedance of a source circuit, the matching circuit includes a first band branch that is associated with a first frequency band, wherein the first band branch includes first band capacitors and first band inductors, wherein the first band capacitors and the first band inductors are configured to set impedances of the first band branch within the first band to fall on a loop that bypasses, within a Smith chart, a source Smith chart point representative of the output impedance of the source circuit.

### CROSS REFERENCE

This application claims priority from US provisional patent Ser. No. 63/496,949 filing date Apr. 18, 2023, which is incorporated herein by reference.

### BACKGROUND

There is an increasing demand for small antennas; more devices are connected through radio whereas the form factor and other demands don't allow large antennas. At the same time the usage would request large bandwidth which needs careful consideration of the selected matching circuit. The situation gets even more complex when the antenna should operate in different conditions/environments. The presented invention addresses both the demand for wide bandwidth and stable operation issues of a small antenna.

There is a growing need to provide an antenna in small size but having a wide bandwidth

### SUMMARY

According to an embodiment, there is provided a matching circuit.

### BRIEF DESCRIPTION OF THE DRAWINGS

The subject matter regarded as the invention is particularly pointed out and distinctly claimed in the concluding portion of the specification. The invention, however, both as to organization and method of operation, together with objects, features, and advantage s thereof, may best be understood by reference to the following detailed description when read with the accompanying drawings in which:

FIGS. 1-10 illustrate examples of parts of a matching circuit or a matching circuits;

FIGS. 11-15 illustrate examples of measurements of a matching circuit;

FIGS. 16-17 illustrate examples of measurements of a matching circuit;

FIG. 18 illustrates an example of a matching circuit;

FIGS. 19-20 illustrate examples of measurements of a matching circuit;

FIG. 21 illustrates an example of a matching circuit;

FIGS. 22-23 illustrate examples of measurements of a matching circuit;

FIG. 24 illustrates an example of a matching circuit;

FIGS. 25-29 illustrate examples of measurements of a matching circuit; and

FIG. 30 illustrates an example of a matching circuit.

### DETAILED EXAMPLE OF THE DRAWINGS

According to an embodiment, there is provided a matching circuit for matching an impedance of an antenna to an output impedance of a source circuit, the matching circuit includes a first band branch that is associated with a first frequency band, wherein the first band branch includes first band capacitors and first band inductors, wherein the first band capacitors and the first band inductors are configured to set impedances of the first band branch within the first band to fall on a loop that bypasses, within a Smith chart, a source Smith chart point representative of the output impedance of the source circuit.

According to an embodiment, a maximal distance (D1) between the source Smith chart point and any of the impedances of the first band branch, is smaller than a maximal distance (D2) between the source Smith chart point and any impedance of the antenna at an absence of the matching circuit.

According to an embodiment, D1 is smaller than D2 by a factor that exceeds two.

According to an embodiment, the one or more capacitors and one of more inductors form:
a. A first band squeezing circuit configured to reduce a range of first band branch impedances related to the first band.
b. A first band looping circuit configured to cause first branch impedances related to the first band to fall on the loop.
c. A first band stretching circuit configured to increase a range of first band branch impedances related to the first band.

According to an embodiment, (i) an input of the first branch squeezing circuit is in communication with a first branch input; (ii) an output of the first branch squeezing circuit is in communication with an input of the first band looping circuit; (c) an output of the first band looping circuit is in communication with an input of the first stretching circuit; and (d) an output of the first stretching circuit is in communication with a first branch output.

According to an embodiment, the first band squeezing circuit includes serially coupled first reactive impedance elements.

According to an embodiment, the first band stretching circuit includes serially coupled first reactive impedance elements.

According to an embodiment, the first band looping circuit includes a parallelly coupled first reactive impedance element.

According to an embodiment, the first band looping circuit includes a first band capacitor.

According to an embodiment, the first band stretching circuit includes a first band capacitor and a first band inductor that is serially coupled to the first band capacitor.

According to an embodiment, the first band stretching circuit includes a pair of serially coupled first band inductors.

According to an embodiment, the first band capacitors and the second band inductors consist essentially of three first band capacitors and two inductors.

According to an embodiment, the matching circuit further includes a second band branch that is associated with a second frequency band that differs from the first frequency band, wherein the second band branch includes second band capacitors and second band inductors, wherein the second band capacitors and the second band inductors are configured to set impedances of the second band branch within the second band to fall on another loop that bypasses, within the Smith chart, the source Smith chart point.

According to an embodiment, the first band branch is parallelly coupled to the second band branch.

According to an embodiment, the first band branch includes a second band stop filter, and the second band branch includes a first band stop filter.

According to an embodiment, a number of first band inductors differs from a number of second band inductors.

According to an embodiment, a number of first band inductors differs from a number of first band capacitor.

According to an embodiment, there is provided a method for impedance matching, the method includes: matching an impedance of an antenna to an output impedance of a source circuit by a matching circuit that includes a first band branch that is associated with a first frequency band, wherein the first band branch includes first band capacitors and first band inductors, wherein the first band capacitors and the first band inductors are configured to set impedances of the first band branch within the first band to fall on a loop that bypasses, within a Smith chart, a source Smith chart point representative of the output impedance of the source circuit.

According to an embodiment, one branch includes two separate frequency ranges (for example—UHF range—378-520 MHz and 757-940 MHz).

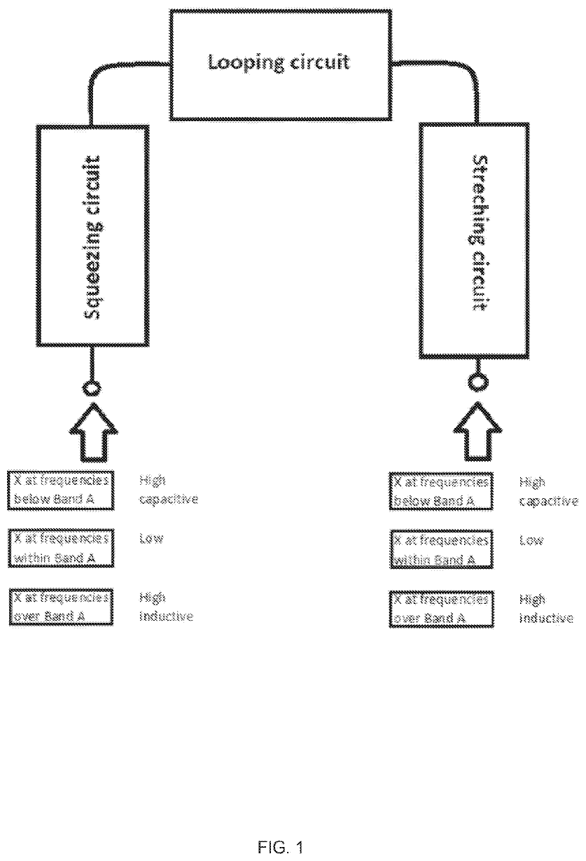

FIG. 1 is one example of a reactance of presented environment resistant matching circuit

The matching circuit of the antenna provides low reactance only over the desired frequency range. Out of the band the reactance is high.

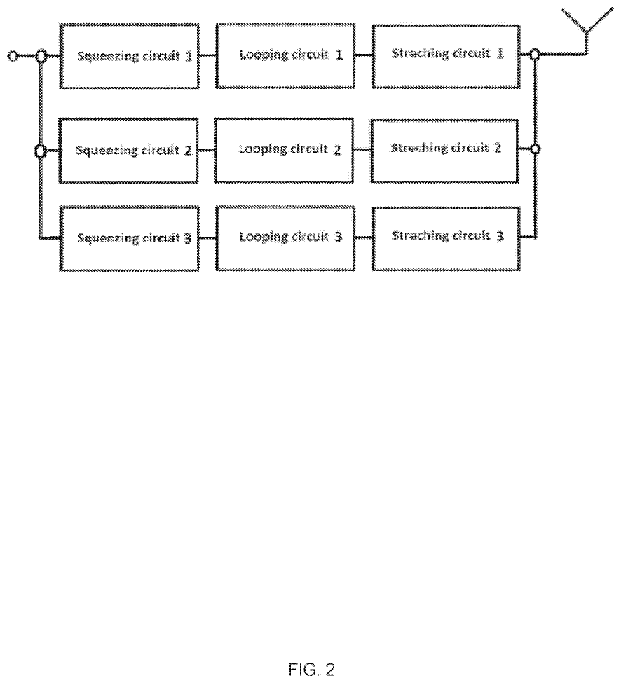

Therefore it is possible combine parallel paths with just a weak disturbance between each others. This would be very useful at least for multiband solutions or matching an antenna utilizing multiband elements. FIG. 2. presents three parallel lines to be used match a multiband element.

FIG. 2 is an example of a multiline environment resistant matching circuit.

In one embodiment of the invention a single radiation element in length of 175 mm on LMR radio is used for VHF, UHF, and 757-870 MHz range, optionally 757-940 MHz range. The antenna theory tells such antenna in VHF range is still capable of a gain of 1.5 dBi, the penalty is a low radiation resistance and therefore a narrow bandwidth. In UHF range such whip is close to the resonance providing resistance not far from the target 50 Ohms.

In 757-940 MHz range the radiation element as the LMR radio provide electrical length of about half wave long. Therefore, the resulting radiation pattern is omnidirectional over all selected bands like needed for such application. With a such long element the radiation resistance is high.

The inductance/capacitance values needed in VHF range differ a lot from values needed for UHF and even more for 757-870 MHz range. Therefore, a practical solution requires a separate path in matching circuit for VHF and second for UHF and 757-870 MHz.

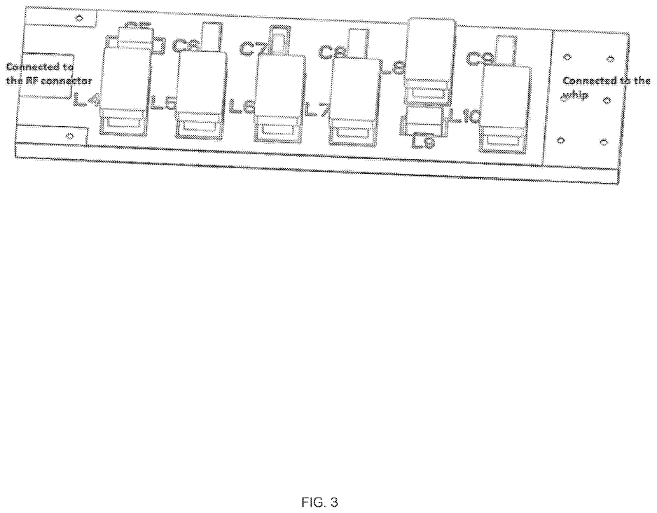

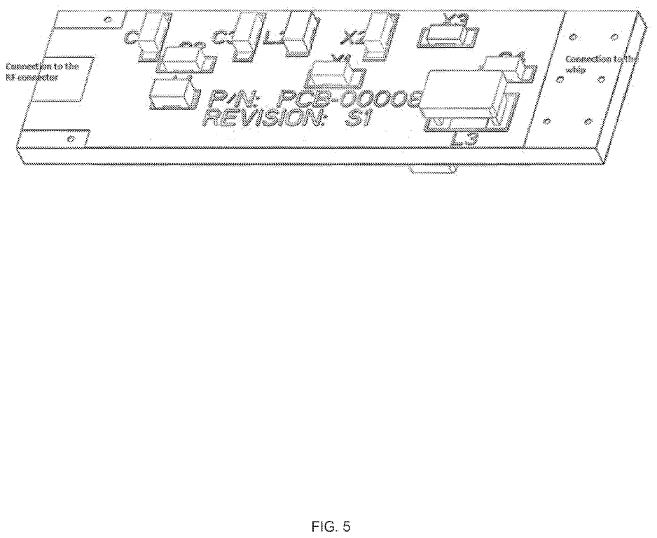

VHF matching is done as described above. The matching circuit is presented in FIG. 3—the side of VHF band and FIG. 5—the side of UHF and 757-940 MHz.

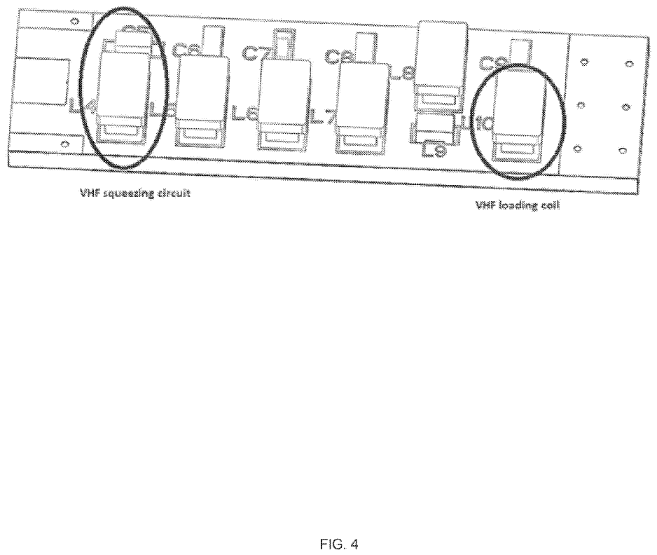

A large loading coil connected to said whip is needed in VHF range to compensate for the strong capacitive reactance of the whip. Said loading coil in same time acts as a high impedance for UHF and 757-870 MHz; doesn't allow those frequencies enter to this path. The squeezing circuit also has a large serial coil preventing UHF and 757-870 MHz band entering from the direction of the RF connector. The loading coil and the squeezing circuit are presented in FIG. 4. FIG. 4 illustrates a location of the VHF loading coil and VHF squeezing circuit.

FIG. 5 illustrates a UHF/757-870 MHz side of the matching circuit PCB.

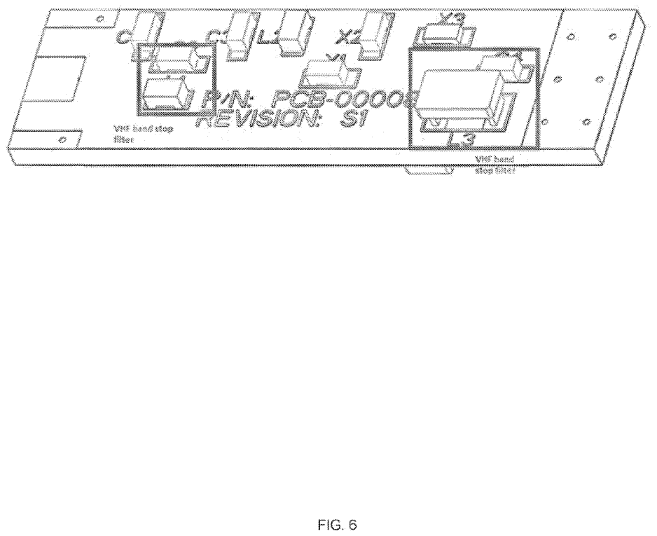

UHF band matching is done with high pass filter. Therefore, it does the required matching allowing wide UHF bandwidth but doesn't affect the 757-870 MHz band. The stretching circuit is replaced by VHF band stop filter having parallel inductor and capacitor. The separation from VHF band requires VHF band stop filter at least in the end connected to the whip. The VHF band stop filters are presented in FIG. 6. The High pass filter matching the UHF band is shown in FIG. 7.

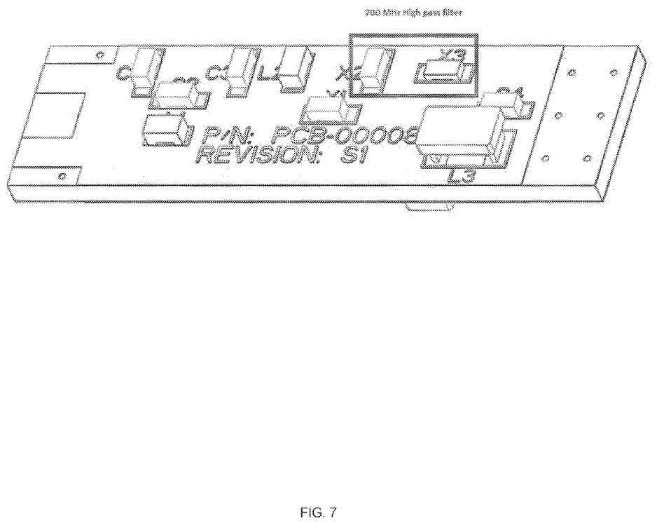

Matching of the 757-870 MHz band is done with more complex looping circuitry where also one of the VHF band-stop filters has a function. The components are shown in FIG. 8 that illustrates a looping circuit of 757-870 MHz band.

To keep the surface area of the matching circuit PCB small enough to produce a round antenna in typical size it is necessary to divide the VHF circuitry on one side and higher frequencies on second side of the PCB.

This causes some problems; there is a coupling between the matching components/traces due to the thin substrate material of the PCB and rather high dielectric constant of the substrate material.

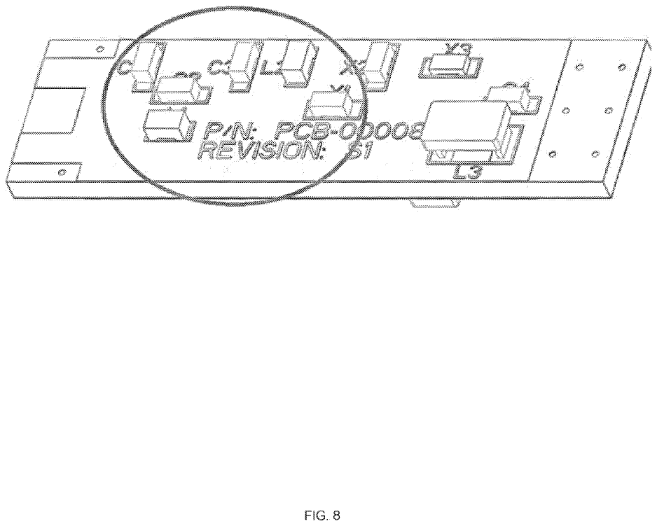

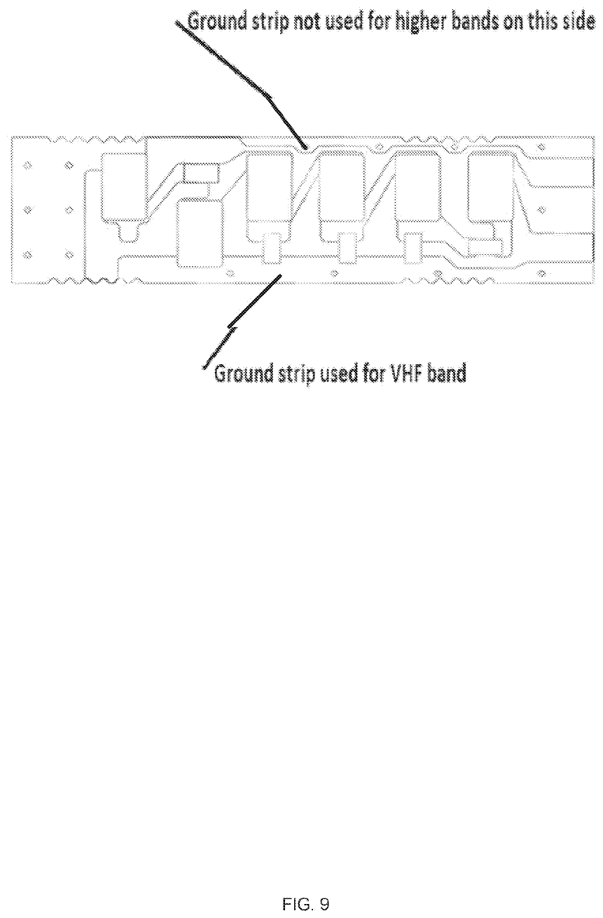

The current invention addresses this problem by using separate ground strips—one strip on one side of the layout only for VHF band and second strip for higher frequencies. Each ground connection strip is connected to the coaxial connector body. The 2 sides of the matching circuit board without soldering mask are shown in FIG. 9 and FIG. 10. FIG. 9 illustrates separated ground strips on the bottom side. FIG. 10 illustrates a separated ground strips on the top side.

A different way to reduce the coupling is to use thicker substrate material. However, one must keep in mind that the connection must remain 50 Ohm. Increase of the substrate thickness makes the end of the center pin connected to the PCB wider which has impact to the impedance. To avoid this a redesign of the center pin/PCB is required. There is a slot in the PCB allowing a nearly cylindrical center pin connect to the 2 sides of the PCB. See FIG. 11 that illustrates a redesign of the center pin and thicker PCB.

These types of antennas are designed for harsh environments. The radio and antenna are subject to mechanical impact. The mechanical solution could be a strong housing around the matching circuit PCB and strong glue filling all space between the housing and assembled PCB. Electrically this is problematic. The dk of the glue returns the antenna. Even worse, the loss tangent causes significant reductions in performance of the antenna even when antenna is tuned again to the required bands. The problem get worse because there is no reliable information available about the dk and loss tangent in required bands. Testing glues with announced low loss tangent did not work in frequencies over 700 MHz.

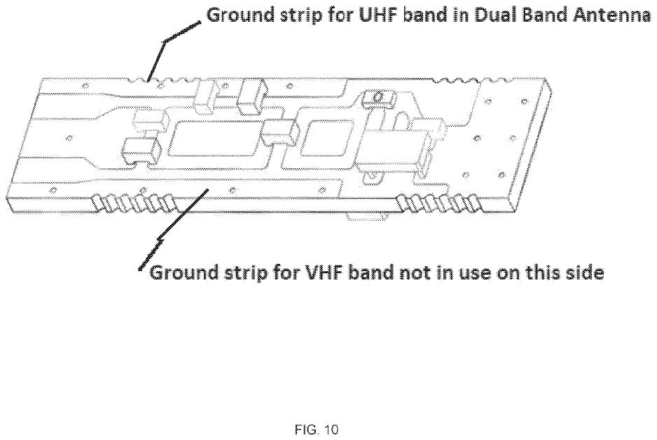

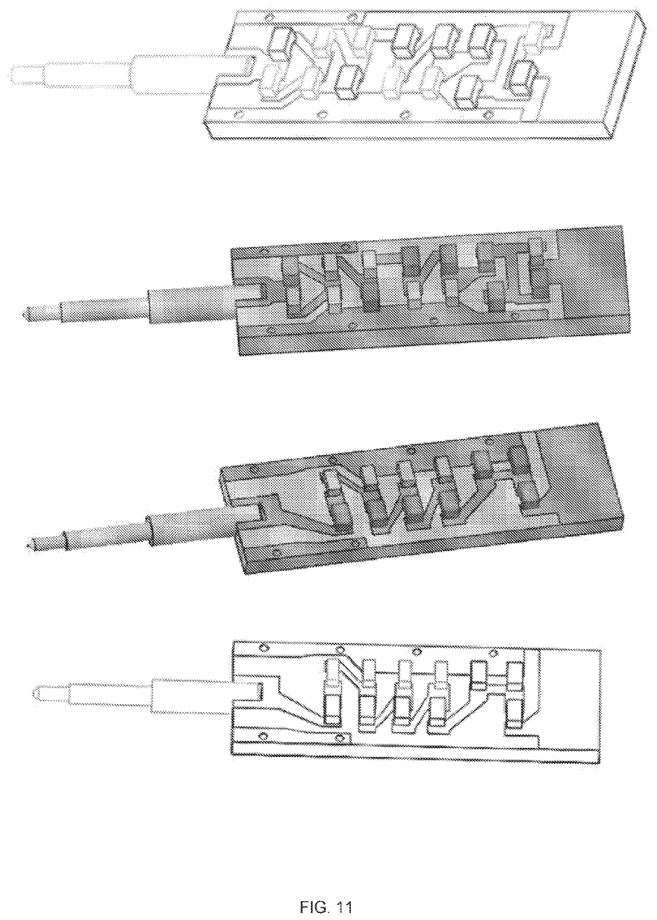

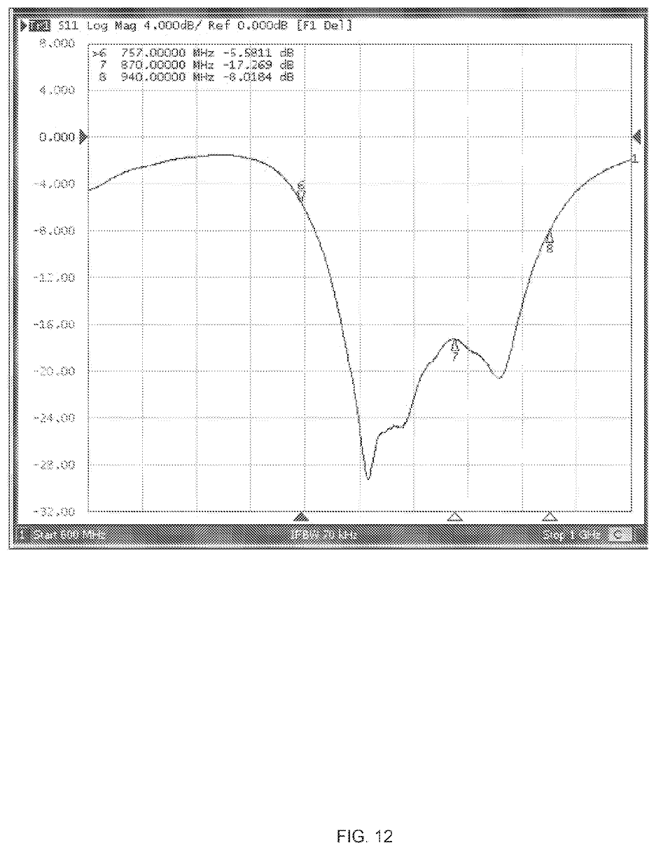

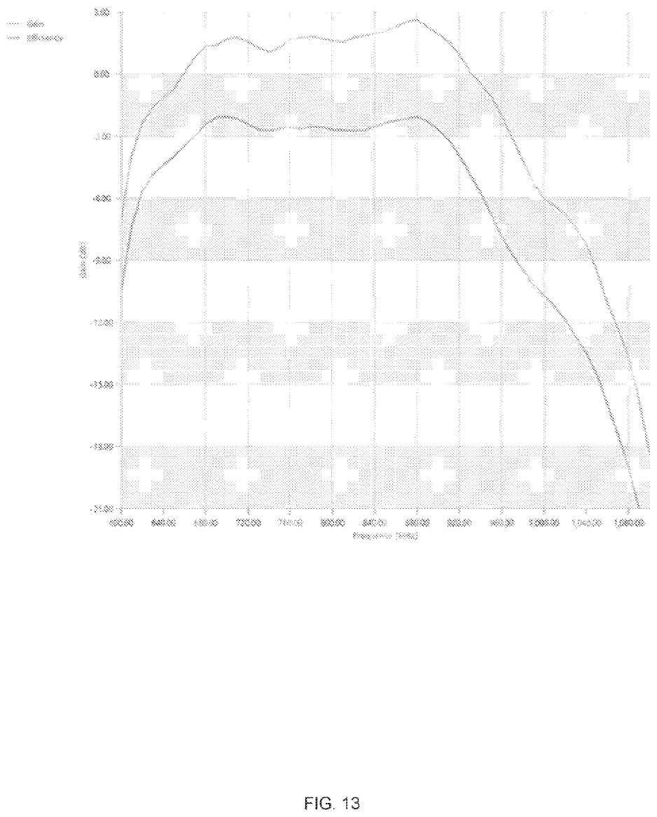

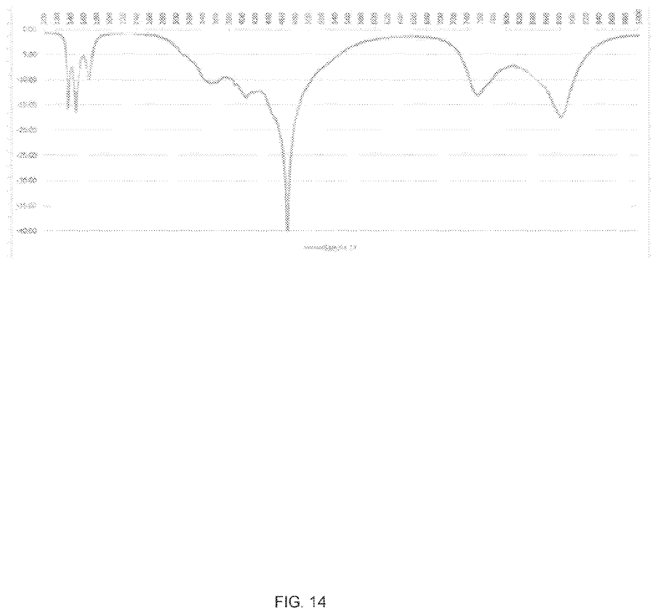

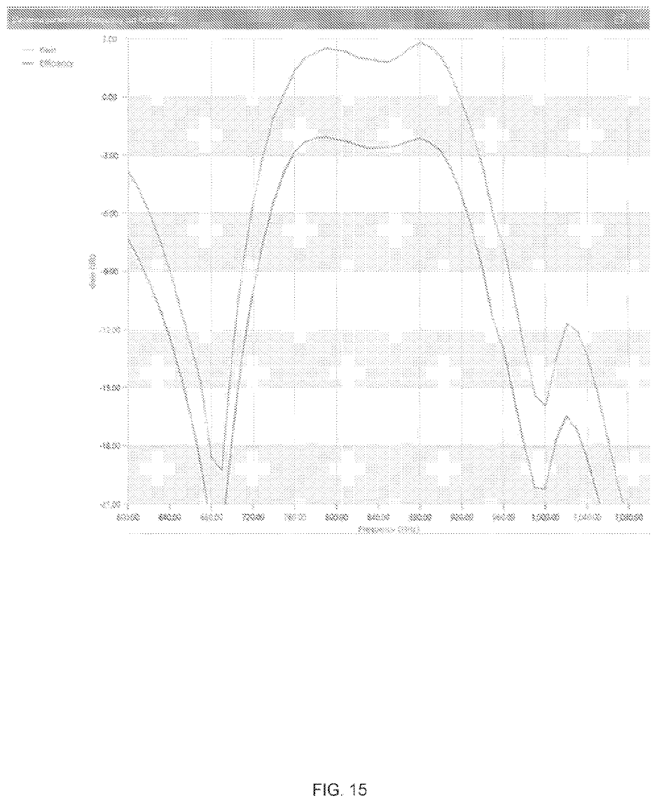

After evaluating different glue materials from different manufacturers, a suitable material was found. FIG. 12 and FIG. 13 show return loss and efficiency of the antenna without glue material. FIG. 14 and FIG. 15 show a return loss and efficiency with compensated matching circuit using selected material. The performance of the required bands of Tri-band versions is very good in both cases. The gain and efficiency are presented only in 700/800 MHz range.

According to an embodiment, the matching circuit is presented using an embodiment in VHF band. A basic quarter wave design at 163.5 MHz would result in a whip nearly 50 cm high over a large ground plane. The presented embodiment has height of 7.5 cm and ground plane diameter of 21 cm. The whole antenna is covered by a round Radom. To optimize the antenna bandwidth, the antenna element occupies most of the volume of the Radom. However, the small size of the antenna limits the radiation resistance to about 8-9 Ohms. A Smith Chart presenting the antenna impedance is presented in FIG. 16.

The return Loss of the antenna with bit higher tuning is presented in FIG. 17.

A matching circuit transferring the antenna impedance close to 50 Ohms is needed. In the specific design of DAS for VHF in Israel the required bandwidth is about 160-167 MHz. The target DAS system can detect an operating antenna if the return loss is better than −9.54 dB. A failure in return loss requires an expensive service visit. These requirements set the design parameters. In addition, a typical installation for the antenna is in height of 2.5-3 meters. Because the wavelength is nearly 2-meter-long objects in distances of couple meters affect to the tuning of the antenna. Antenna should be able to maintain the required return loss regardless of possible changes in the environment.

A simple 2 component matching circuit can match any frequency to the target impedance, here to 50 Ohms. However, in such an antenna the difference between the impedances at 160 MHz and at 167 MHz is so large that the required bandwidth cannot be reached with the simple 2 component circuit. The reachable bandwidth with return loss −9.54 dB would be in the range 2-3 MHz. The result could be improved by making the transfer in steps. Here a novel way is presented.

An additional serial resonance circuit doesn't cause change in the impedance at resonance frequency. Schematic presentation of the circuit in FIG. 18.

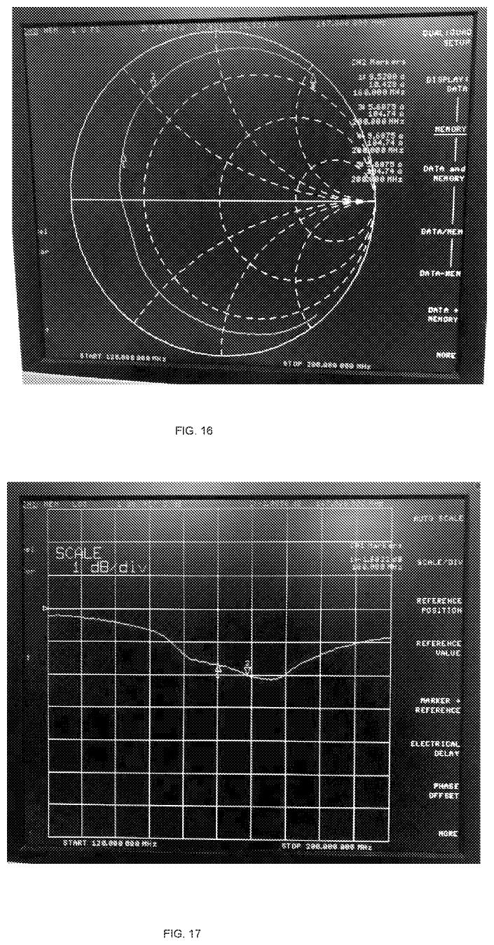

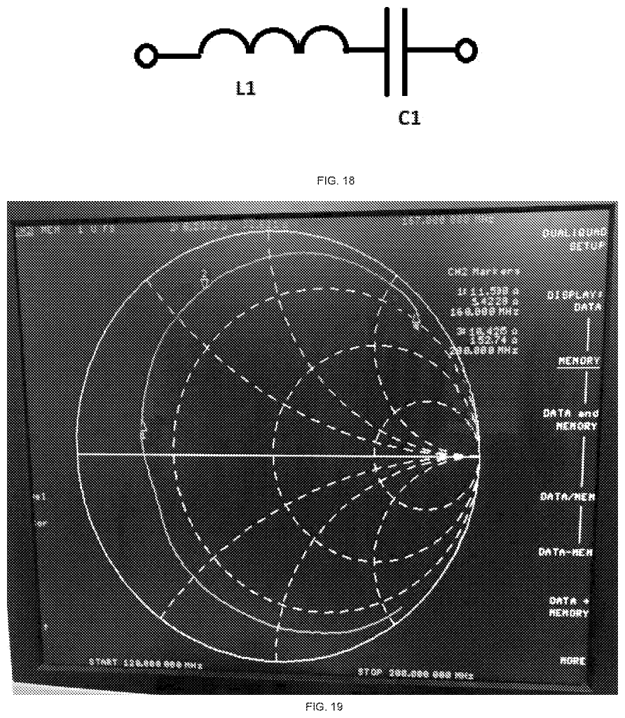

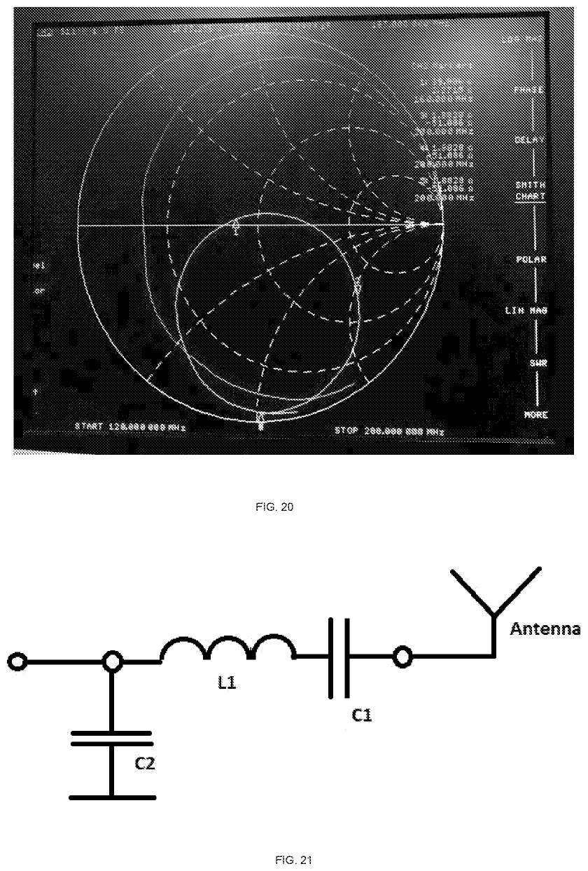

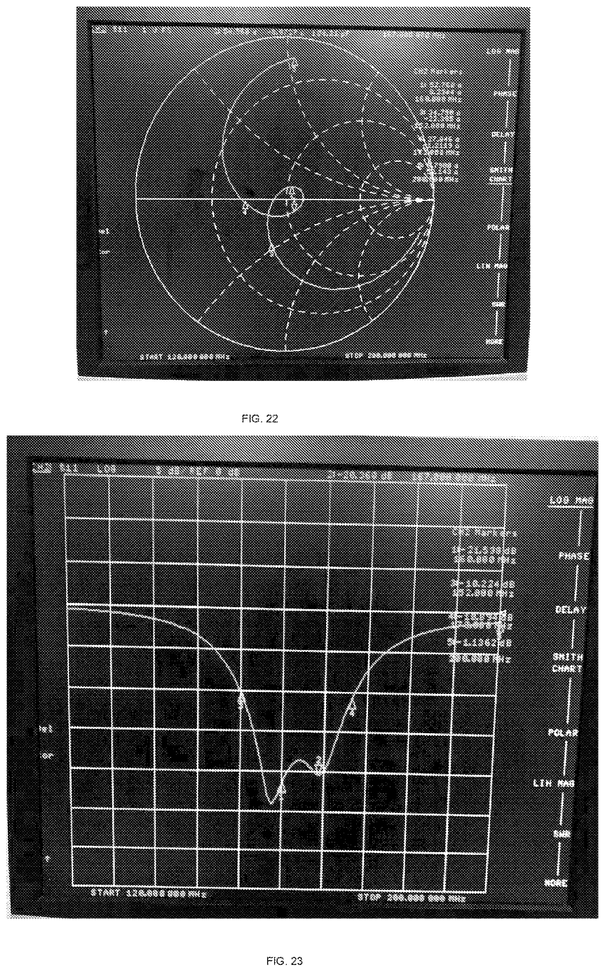

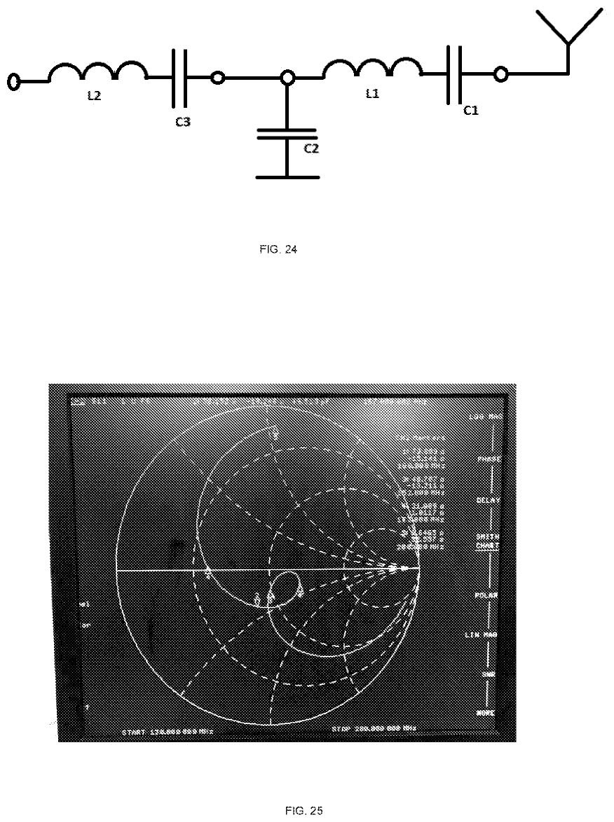

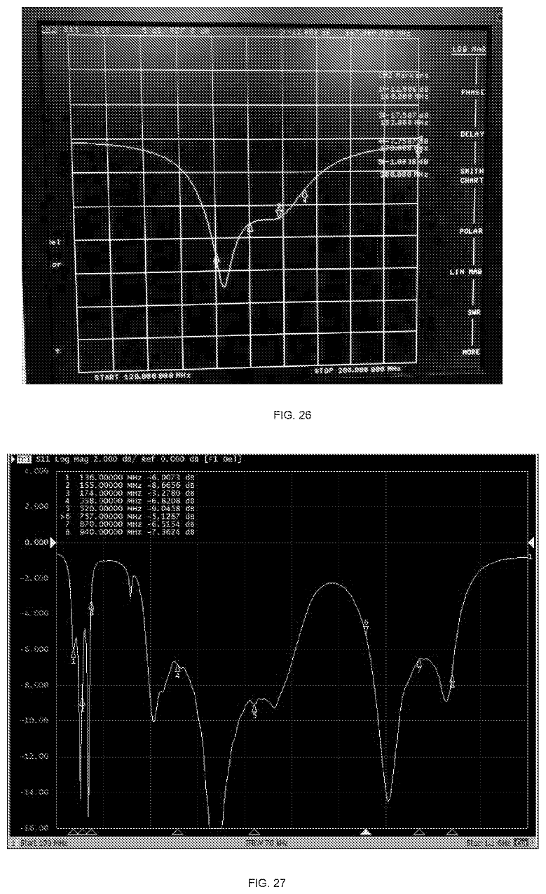

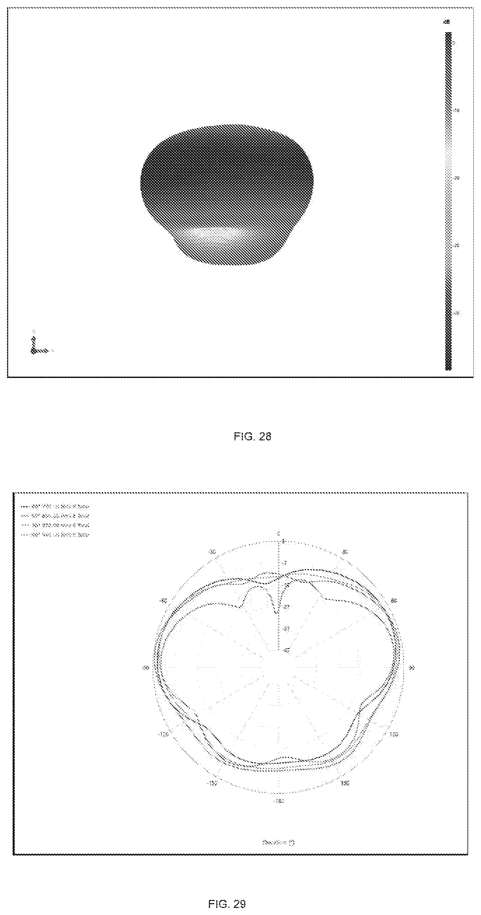

At higher frequencies the circuit presents some value of inductance, at lower frequencies the circuit presents some value of capacitance. One can stretch the impedances of the highest frequencies more apart from the impedances of the lowest frequencies by adding such circuit having the resonance frequency at 163.5 MHz. This is presented in the Smith Chart as seen in FIG. 19—the matching got worse.

With some other antenna designs this stretching might not be needed.

However, by selecting the location of the required band in a suitable area of the Smith Chart—here in inductive area—(capacitive area is also possible) one can with a single capacitor bend the graph of impedances of the required band in the Smith Chart to bypass 50 Ohms. The change of the antenna impedance is shown in figure

The matching circuit so far consist of the following components shown in FIG. 21.

Now the locations of the lowest frequencies and highest frequencies have changed in the way that highest frequencies have capacitive value. By implementing a serial resonance circuit, a second time the highest impedances are moving towards impedances of the lowest frequencies squeezing the impedance graph over required band. Result shown in FIG. 22 the result also includes a small length addition to the antenna element.

The return loss of the antenna is shown in FIG. 23.

Final matching circuit for small VHF antenna is shown in FIG. 24.

In essence the matching circuit builds up a small loop around the 50 Ohms point with nearly constant distance from it instead of line bypassing 50 Ohms point.

This gives a new nature for the antenna/matching. If there is change in environment causing the antenna element to look longer (lower tuning) the impedance both in lowest and highest frequencies remains close to 50 Ohms point. Marker 2 at 167 MHz moves toward Marker 4 at 173 MHz and Marker 1 at 160 MHz moves toward Marker 2 at 167 MHz of an unaffected antenna.

Similar effect will occur also if the environment causes the antenna element to have higher tuning. Marker 1 at 160 MHz moves toward Marker 3 at 152 MHz and Marker 2 at 167 MHz moves toward Marker 1 at 160 MHz of an unaffected antenna.

The impedances of the required band seem to have nearly constant distance to 50 Ohms point—constant return loss, it just rotates around the 50 Ohms point clockwise or anticlockwise.

The Smith Chart of FIG. 26 shows result when the antenna is disturbed by laying hand over some location of the Radom, a strong disturbance.

Change in Return Loss is shown in FIG. 27. The return loss in targeted band remains within the specification.

The schematic of a environment resistant matching circuit presented in FIG. 25 is not limited to VHF band nor to the components presented in embodiment for a VHF DAS antenna design.

If a capacitor is considered as a looping circuit in the presented embodiment it can be replaced by an inductor when a suitable location on Smith chart for the required band is maintained. In most cases more complex circuitry for looping circuit is needed.

Further for very small antennas a loading concept is used for example by locating a serial inductor to the feed point. A stretching circuit might be in such case combined with the loading circuit.

Further the layout of each presented circuit—for stretch, loop and squeeze—might be modified according to specific need. It may be useful to use band stop filter instead of stretching circuit.

Further more both the stretching circuit and the squeezing circuit can be considered to act as a bandpass filter presenting very high capacitive or inductive reactance outside the band. See, FIG. 1.

Therefore it is possible combine parallel paths with just a weak disturbance between each others. This would be very useful at least for multiband solutions or matching an antenna utilizing multiband elements. See, for example FIG. 2 that presents 3 parallel lines to be used match a multiband element.

In another embodiment of the invention a single radiation element in length of 175 mm on LMR radio is used for VHF, UHF, and 757-870 MHz range, optionally 757-940 MHz range. The antenna theory tells such antenna in VHF range is still capable of gain 1.5 dBi; the penalty is a low radiation resistance and therefore a narrow bandwidth. In UHF range such whip is close to the resonance providing resistance not far from the target 50 Ohms.

In 757-940 MHz range the radiation element as the LMR radio provide electrical length of about half wave long. Therefore, the resulting radiation pattern is omnidirectional over all selected bands like needed for such application. With a such long element the radiation resistance is high.

The inductance/capacitance values needed in VHF range differ a lot from values needed for UHF and even more for 757-960 MHz range. Therefore, a practical solution requires a separate path in matching circuit for VHF and second for UHF and 757-940 MHz.

VHF matching is done as described above. The matching circuit is presented in FIG. 3—the side of VHF band and Pic 17—the side of UHF and 757-940 MHz.

A large loading coil connected to said whip is needed to compensate for the strong capacitive reactance of the whip. Said loading coil in same time acts as a high impedance for UHF and 757-940 MHz; doesn't allow those frequencies enter to this path. The squeezing circuit also has a large serial coil preventing UHF and 757-940 MHz band entering from the direction of the RF connector. The loading coil and the squeezing circuit are presented in FIG. 4.

UHF band matching is done with high band pass filter. Therefore, it does the required matching allowing wide UHF bandwidth but doesn't affect the 757-960 MHz band. The stretching circuit is replaced by VHF band stop filter having parallel inductor and capacitor. The separation from VHF band requires VHF band stop filter at least in the end connected to the whip. The VHF band stop filters are presented in FIG. 5. The High pass filter matching the UHF band is shown in FIG. 6.

Matching of the 757-940 MHz band is done with more complex looping circuitry where also one of the VHF band stop filters has a function. The components are shown in FIG. 7.

Measurement results of LMR antenna according to the invention

Return Loss of the Antenna is shown in FIG. 26.

Efficiency and Realized Gain over 757-940 MHz is shown in FIG. 27.

3D Pattern at 800 MHz is shown in FIG. 28. The elevation pattern at various frequencies in 757-940 MHz band is shown in FIG. 29.

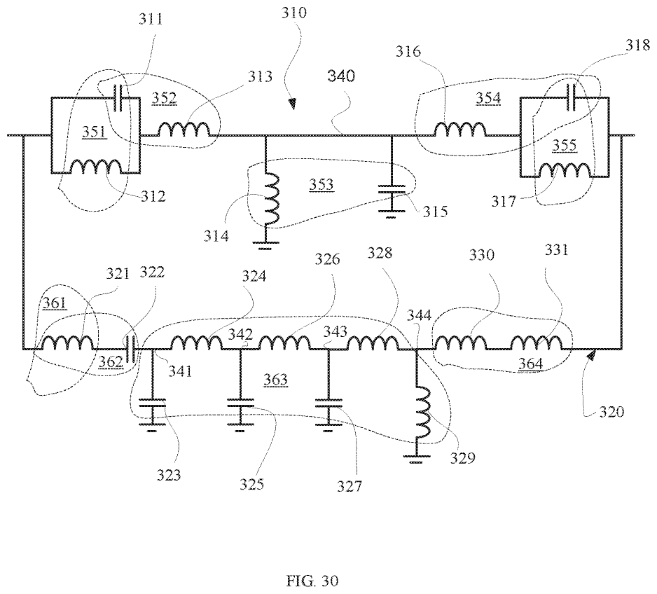

FIG. 30 illustrates an example of a matching circuit 300 that includes a first band (FB) branch 310 and a second band (SB) branch 320.

According to an embodiment, the FB branch 310 includes first FB capacitor 311, first FB inductor 312, second FB inductor 313, third FB inductor 314, second FB capacitor 315, fourth LB inductor 316, fifth FB inductor 317 and third FB capacitor 318.

A first pair of reactive impedance elements includes parallelly coupled first FB capacitor 311 and first FB inductor 312. The first pair is serially coupled between an FB branch input and second FB inductor 313. An output of the second FB inductor 313, one end of the third FB inductor 314, one end of second FB capacitor 315 and an input of fourth FB inductor 316 are coupled to first intermediate junction 340. An end of fourth FB inductor 316 is coupled to a second pair of reactive impedance elements that includes parallelly coupled third FB capacitor 318 and fifth FB inductor 317.

According to an embodiment, the SB branch 320 includes first SB inductor 321, first SB capacitor 322, second SB capacitor 323, second SB inductor 324, third SB capacitor 325, third SB inductor 326, fourth SB capacitor 327, fourth SB inductor 328, fifth SB inductor 329, sixth SB inductor 330 and seventh SB inductor 331.

An input of first SB inductor 321 is coupled to an input of the second branch. An output of the first SB inductor 321 is coupled to an input of first SB capacitor 322. An output of first SB capacitor 322, a first end of second SB capacitor 323 and an input of second SB inductor 324 are coupled to second intermediate junction 341. An output of second SB inductor 324, a first end of third SB capacitor 325 and an input of third SB inductor 326 are coupled to third intermediate junction 342.

An output of third SB inductor 326, a first end of fourth SB capacitor 327 and an input of fourth SB inductor 328 are coupled to fourth intermediate junction 343.

An output of fourth SB inductor 328, a first end of fifth SB inductor 329 and an input of sixth SB inductor 330 are coupled to fifth intermediate junction 344. The seventh SB inductor 331 is serially coupled between the output of sixth SB inductor 330 and an output of the second branch.

An input FB band stop 351 is formed by first FB capacitor 311 and first FB inductor 312.

A FB squeezing circuit 352 is formed by first FB capacitor 311 and second FB inductor 313.

A FB looping circuit 353 is formed by third FB inductor 314 and second FB capacitor 315.

An output FB band stop 355 is formed by fifth FB inductor 317 and third FB capacitor 318.

A FB stretching circuit 354 is formed by fourth LB inductor 316 and third FB capacitor 318.

An input SB band stop 361 is formed first SB inductor 321.

A SB squeezing circuit 362 is formed by first SB inductor 321 and first SB capacitor 322.

A SB looping circuit 363 is formed by second SB capacitor 323, second SB inductor 324, third SB capacitor 325, third SB inductor 326, fourth SB capacitor 327, fourth SB inductor 328, and fifth SB inductor 329.

A SB stretching circuit 364 is formed by sixth SB inductor 330 and seventh SB inductor 331.

According to an embodiment, the first band is a UHF and 700-900 Mhz frequency, and the second band is a VHF. The inductance of the inductors of the FB range between 5-110 nanoHenry, the capacitances of the capacitors of the FB range between 3-20 picoFarad, the inductance of the inductors of the SB range between 40-300 nanoHenry, the capacitances of the capacitors of the FB range between 3-25 picoFarad.

In the foregoing detailed description, numerous specific details are set forth in order to provide a thorough understanding of the invention. However, it will be understood by those skilled in the art that the present invention may be practiced without these specific details. In other instances, well-known methods, procedures, and components have not been described in detail so as not to obscure the present invention.

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

Any reference to any of the terms “comprise”, “comprises”, “comprising” “including”, “may include” and “includes” may be applied to any of the terms “consists of”, “consisting of”, “consisting essentially of”. For example—any of the rectifying circuits illustrated in any figure may include more components than those illustrated in the figure, only the components illustrated in the figure or substantially only the components illustrated in the figure.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Those skilled in the art will recognize that the boundaries between logic blocks are merely illustrative and that alternative embodiments may merge logic blocks or circuit elements or impose an alternate decomposition of functionality upon various logic blocks or circuit elements. Thus, it is to be understood that the architectures depicted herein are merely exemplary, and that in fact many other architectures can be implemented which achieve the same functionality.

Any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “operably connected,” or “operably coupled,” to each other to achieve the desired functionality.

Furthermore, those skilled in the art will recognize that boundaries between the above described operations are merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

Also, for example, in one embodiment, the illustrated examples may be implemented as circuitry located on a single integrated circuit or within a same device. Alternatively, the examples may be implemented as any number of separate integrated circuits or separate devices interconnected with each other in a suitable manner.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps than those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim

1. A matching circuit for matching an impedance of an antenna to an output impedance of a source circuit, the matching circuit includes a first band branch that is associated with a first frequency band, wherein the first band branch includes first band capacitors and first band inductors, wherein the first band capacitors and the first band inductors are configured to set impedances of the first band branch within the first band to fall on a loop that bypasses, within a Smith chart, a source Smith chart point representative of the output impedance of the source circuit.

2. According to an embodiment, (a) a maximal distance between the source Smith chart point and any of the impedances of the first band branch, is smaller than (b) a maximal distance between the source Smith chart point and any impedance of the antenna at an absence of the matching circuit.

3. According to an embodiment, (a) is smaller than (b) by a factor that exceeds two.

4. According to an embodiment, the one or more capacitors and one of more inductors form:
a. a first band squeezing circuit configured to reduce a range of first band branch impedances related to the first band;
b. a first band looping circuit configured to cause first branch impedances related to the first band to fall on the loop; and
c. a first band stretching circuit configured to increase a range of first band branch impedances related to the first band.

5. According to an embodiment, an input of the first branch squeezing circuit is in communication with a first branch input;
wherein an output of the first branch squeezing circuit is in communication with an input of the first band looping circuit;
wherein an output of the first band looping circuit is in communication with an input of the first stretching circuit; and
wherein an output of the first stretching circuit is in communication with a first branch output.

6. According to an embodiment, the first band squeezing circuit includes serially coupled first reactive impedance elements.

7. According to an embodiment, the first band stretching circuit includes serially coupled first reactive impedance elements.

8. According to an embodiment, the first band looping circuit includes a parallelly coupled first reactive impedance element.

9. According to an embodiment, the first band looping circuit includes a first band capacitor.

10. According to an embodiment, the first band stretching circuit includes a first band capacitor and a first band inductor that is serially coupled to the first band capacitor.

11. According to an embodiment, the first band stretching circuit includes a pair of serially coupled first band inductors.

12. According to an embodiment, the first band capacitors and the second band inductors consist essentially of three first band capacitors and two inductors.

13. The matching circuit according to further includes a second band branch that is associated with a second frequency band that differs from the first frequency band, wherein the second band branch includes second band capacitors and second band inductors, wherein the second band capacitors and the second band inductors are configured to set impedances of the second band branch within the second band to fall on another loop that bypasses, within the Smith chart, the source Smith chart point.

14. According to an embodiment, the first band branch is parallelly coupled to the second band branch.

15. According to an embodiment, the first band branch includes a second band stop filter, and the second band branch includes a first band stop filter.

16. According to an embodiment, a number of first band inductors differs from a number of second band inductors.

17. According to an embodiment, a number of first band inductors differs from a number of first band capacitor.

18. A method for impedance matching, the method includes: matching an impedance of an antenna to an output impedance of a source circuit by a matching circuit that includes a first band branch that is associated with a first frequency band, wherein the first band branch includes first band capacitors and first band inductors, wherein the first band capacitors and the first band inductors are configured to set impedances of the first band branch within the first band to fall on a loop that bypasses, within a Smith chart, a source Smith chart point representative of the output impedance of the source circuit.
